(19) United States
(12) Patent Application Publication
(10) Pub. No.: US 2010/0230758 A1
(43) Pub. Date: Sep. 16, 2010

(54) SEMICONDUCTOR DEVICE WITH IMPROVED STRESSOR SHAPE

(76) Inventors: Chong Kwang CHANG, Bucheon-si (KR); HwaSung Rhee, Fishkill, NY (US); MyungSun Kim, Hwaseong-si (KR); NaeIn Lee, Seoul (KR); HongJae Shin, Seoul (KR)

Correspondence Address: F. CHAU & ASSOCIATES, LLC, 130 WOODBURY ROAD, WOODBURY, NY, 11797, US

(21) Appl. No.: 12/697,572

(22) Filed: Feb. 1, 2010

(30) Foreign Application Priority Data
Feb. 2, 2009 (KR) 10-2009-0007980

(51) Int. Cl. H01L 27/088; H01L 21/71

(52) U.S. Cl. 257/368; 438/429; 257/E27.06; 257/E21.536

(57) ABSTRACT

A formation method and resulting strained semiconductor device are provided, the formation method including forming transistors on a substrate, each transistor having a gate disposed over a channel region, etching or annealing an elongated trench between adjacent channel regions, where the trench has a lower boundary that is deeper towards its ends than towards its center, and conformably embedding an elongated stress region in the trench between adjacent channel regions; and the resulting strained semiconductor device including transistors, each having a gate disposed over a channel region, and elongated stress regions disposed between adjacent channel regions, wherein each of the elongated stress regions has a lower boundary that is deeper towards its ends than towards its center.

### CROSS-REFERENCE TO RELATED APPLICATION

This application claims foreign priority under 35 U.S.C. §119 to Korean Patent Application No. P2009-0007980 (Atty. Dkt. ID-200810-023-1), filed on Feb. 2, 2009, in the Korean Intellectual Property Office, the disclosure of which is incorporated by reference herein in its entirety.

### BACKGROUND OF THE INVENTION

The present disclosure generally relates to semiconductor manufacturing and lithography methods. More particularly, the present disclosure relates to methods for inducing uniaxial stress by a lattice mismatch in semiconductor devices.

Classical scaling has reached the point of diminishing returns as transistor dimensions continue to decrease. Next node power, performance and density goals may be addressed using process technology.

For increased circuit density, process-induced carrier mobility may be increased to enhance transistor performance. Increased carrier mobility in transistor channels enables higher drive currents. Thus, supply voltages may be reduced to limit power dissipation.

Tensile strain generally increases carrier mobility in negative-channel metal oxide semiconductor (PMOS) devices, while compressive strain generally increases carrier mobility in positive-channel metal oxide semiconductor (NMOS) devices. Highly tensile stress liners for NMOS devices are currently available, and highly compressive stress liners for PMOS devices are under development.

### SUMMARY OF THE INVENTION

The present disclosure teaches a semiconductor device and method of manufacture for inducing uniaxial stress by a lattice mismatch. Exemplary embodiments are provided.

An exemplary embodiment strained semiconductor device is provided, comprising: a plurality of transistors, each having a gate disposed over a channel region; and elongated stress regions disposed between adjacent channel regions, wherein each of the elongated stress regions has a lower boundary that is deeper towards its ends than towards its center.

A further embodiment device is provided wherein each of the elongated stress regions has a substantially non-concave upper boundary. A further embodiment device is provided wherein each of the elongated stress regions has an upper boundary at least as high as the gate. A further embodiment device is provided wherein the channel regions are positively charged. A further embodiment device is provided wherein each of the plurality of transistors is a Positive channel Field Effect Transistor (PFET). A further embodiment device is provided wherein the stress regions are expansive. A further embodiment device is provided wherein the stress regions exert compressive stress against the channel regions. A further embodiment device is provided wherein the stress regions comprise embedded silicon-germanium (SiGe). A further embodiment device is provided wherein the lower boundary of each elongated stress region is substantially concave.

Another embodiment device is provided, further comprising a substrate region disposed beneath each stress region, wherein the substrate region has an upper boundary that is substantially convex. Yet another embodiment device is provided, further comprising a source/drain (S/D) region disposed beneath each stress region, wherein the S/D region has an upper boundary that is substantially convex.

Another embodiment device is provided, further comprising an etch stop layer (ESL) disposed above each stress region, wherein the ESL has a lower boundary that is substantially flat. A further embodiment device is provided wherein the stress region has an upper boundary that is at least as high as a top of the channel. A further embodiment device is provided wherein the channel has substantially vertical sidewalls. A further embodiment device is provided wherein the lower boundary of the stress region meets its ends with an included angle between about 80 degrees to about 120 degrees. A further embodiment device is provided wherein the elongated stress region has an upper boundary that is at least as high towards its center as it is at its ends.

A further embodiment device is provided wherein one end of the elongated stress region is disposed at a source or drain of a first transistor and the other end of the elongated stress region is disposed at a drain or source of the second transistor. A further embodiment device is provided wherein the stress regions have substantially vertical boundaries at the channel regions.

An exemplary embodiment method of forming a strained semiconductor device is provided, the method comprising: forming a plurality of transistors on a substrate, each transistor having a gate disposed over a channel region; at least one of etching or annealing an elongated trench between adjacent channel regions, where the trench has a lower boundary that is deeper towards its ends than towards its center; and conformably embedding an elongated stress region in the trench between adjacent channel regions.

A further embodiment method is provided wherein the embedded stress region has a substantially non-concave upper boundary. A further embodiment method is provided wherein the embedded stress region has an upper boundary at least as high as the gate. A further embodiment method is provided wherein the stress regions have substantially vertical boundaries at the channel regions.

A further embodiment method is provided wherein the channel region is positively charged and the stress region comprises embedded SiGe. A further embodiment method is provided, further comprising forming an elongated oxidation layer between first and second transistors prior to forming the trench, the oxidation layer having one thickness towards its center, and a sloping reduced thickness towards it ends. A further embodiment method is provided wherein the oxidation layer is formed by plasma deposition.

A further embodiment method is provided wherein the center of the trench is elevated at an acute angle relative to the ends of the trench. A further embodiment method is provided wherein the etching is anisotropic.

An exemplary embodiment memory card device having a strained semiconductor NAND flash memory is provided, comprising: a plurality of transistors, each having a gate disposed over a channel region; and elongated stress regions disposed between adjacent channel regions, wherein each of the elongated stress regions has a lower boundary that is deeper towards its ends than towards its center.

A further embodiment memory card device is provided wherein each of the elongated stress regions has a substantially non-concave upper boundary. A further embodiment memory card device is provided wherein each of the elongated stress regions has an upper boundary at least as high as the gate. A further embodiment memory card device is provided wherein the channel regions are positively charged. A further embodiment memory card device is provided wherein each of the plurality of transistors is a Positive channel Field Effect Transistor (PFET). A further embodiment memory card device is provided wherein the stress regions are expansive. A further embodiment memory card device is provided wherein the stress regions exert compressive stress against the channel regions. A further embodiment memory card device is provided wherein the stress regions comprise embedded silicon-germanium (SiGe). A further embodiment memory card device is provided wherein the lower boundary of each elongated stress region is substantially concave.

Another embodiment memory card device is provided, further comprising a substrate region disposed beneath each stress region, wherein the substrate region has an upper boundary that is substantially convex. Yet another embodiment memory card device is provided, further comprising a source/drain (S/D) region disposed beneath each stress region, wherein the S/D region has an upper boundary that is substantially convex.

Another embodiment memory card device is provided, further comprising an etch stop layer (ESL) disposed above each stress region, wherein the ESL has a lower boundary that is substantially flat. A further embodiment memory card device is provided wherein the stress region has an upper boundary that is at least as high as a top of the channel. A further embodiment memory card device is provided wherein the channel has substantially vertical sidewalls. A further embodiment memory card device is provided wherein the lower boundary of the stress region meets its ends with an included angle between about 80 degrees to about 120 degrees. A further embodiment memory card device is provided wherein the elongated stress region has an upper boundary that is at least as high towards its center as it is at its ends.

A further embodiment memory card device is provided wherein one end of the elongated stress region is disposed at a source or drain of a first transistor and the other end of the elongated stress region is disposed at a drain or source of the second transistor. A further embodiment memory card device is provided wherein the stress regions have substantially vertical boundaries at the channel regions.

The present disclosure will be further understood from the following description of exemplary embodiments, which is to be read in connection with the accompanying drawings.

### BRIEF DESCRIPTION OF THE DRAWINGS

The present disclosure provides a formation method and resulting semiconductor device for inducing uniaxial stress by a lattice mismatch in accordance with the following exemplary figures, in which:

FIG. 1 shows schematic diagrams of method steps and resulting intermediate device stages analyzed with a virtual scanning electron microscope (VSEM) during step-by-step formation of an embedded silicon germanium (e-SiGe) recess;

FIG. 2 shows a schematic diagram with table of a single positive-channel field effect transistor (pFET) in the device of FIG. 1 having an e-SiGe shape measured via cross-sectional transmission electron microscopy (XTEM);

FIG. 3 shows comparative schematic diagrams of the e-SiGe shape of FIG. 2 as compared with a second e-SiGe shape in accordance with an exemplary embodiment of the present disclosure;

FIG. 4 shows a schematic diagram of the second positive-channel metal oxide semiconductor (PMOS) device of FIG. 3 in accordance with an exemplary embodiment of the present disclosure;

FIG. 5 shows schematic diagrams with table of three additional embedded stressor region profiles in accordance with exemplary embodiments of the present disclosure;

FIG. 6 shows comparative schematic diagrams of stressor region profiles and resulting stress contours for the shape of FIG. 2 compared with the shape of FIG. 4 in accordance with an exemplary embodiment of the present disclosure;

FIG. 7 shows comparative schematic and graphical diagrams of strain contours for the stressor profiles of FIG. 6 in accordance with exemplary embodiments of the present disclosure;

FIG. 8 shows a schematic diagram of a semiconductor device in accordance with another exemplary embodiment of the present disclosure;

FIG. 9 shows a schematic diagram for an enlarged region of FIG. 8 in accordance with an exemplary embodiment of the present disclosure;

FIG. 10 shows a schematic diagram of a device in process following a method step of producing the device of FIGS. 8 and 9 in accordance with exemplary embodiments of the present disclosure;

FIG. 11 shows a schematic diagram of a device in process following a method step subsequent to that of FIG. 10 for producing the device of FIGS. 8 and 9 in accordance with an exemplary embodiment of the present disclosure;

FIG. 12 shows a schematic diagram of an enlarged region of FIG. 11 in accordance with an exemplary embodiment of the present disclosure;

FIG. 13 shows a schematic diagram of a device in process following a method step subsequent to that of FIGS. 11 and 12 for producing the device of FIGS. 8 and 9 in accordance with an exemplary embodiment of the present disclosure;

FIG. 14 shows a schematic diagram of an enlarged region of FIG. 13 in accordance with an exemplary embodiment of the present disclosure;

FIG. 15 shows comparative schematic diagrams of stressor region profiles for the embodiments of FIGS. 2 and 14 in accordance with an exemplary embodiment of the present disclosure;

FIG. 16 shows comparative schematic diagrams of induced strain contours for the stressor profiles of FIG. 15 in accordance with exemplary embodiments of the present disclosure;

FIG. 17 shows comparative graphical diagrams of stress versus strain curves for the stress contours of FIG. 15 and the strain contours of FIG. 16 in accordance with an exemplary embodiment of the present disclosure; and

FIG. 18 shows a schematic block diagram for a flash memory card system having a strained semiconductor NAND flash memory in accordance with an exemplary embodiment of the present disclosure.

### DETAILED DESCRIPTION OF PREFERRED EMBODIMENTS

A semiconductor device and related method of manufacture are provided for improving carrier mobility through a transistor channel. The method optimizes the uniaxial stress induced in channel regions of the device underneath the gate electrodes by constructing the stress layer with a concave lower surface. Exemplary embodiment positive-channel field effect transistors (pFETs) are capable of superior performance relative to previous pFETs using e-SiGe as the compressive stressor.

There are two basic types of strain enhanced mobility. Process-induced strain generally creates uniaxial strain in one direction, while intrinsic strain generally creates bi-axial strain by stressing a substrate in two directions.

In negative-channel field effect transistors (nFETs), the carriers are electrons. In positive-channel field effect transistors (pFETs), the carriers are holes. Electrons move faster in a (100) oriented silicon substrate, while holes move faster in a (110) oriented silicon substrate.

Fortunately, stressor techniques are primarily additive. For example, compressive stress liners and SiGe source/drain (S/D) enhancement may be combined to achieve the mobility enhancement desired for each transistor, such as balancing the performance of pFETs and nFETs in a complementary metal-oxide semiconductor (CMOS) device, and to increase drive current.

In NAND flash memories, for example, induced strain may be used to improve charge retention and reduce tunneling leakage current. Compressive nitride may be deposited over the gates of pFETs, and tensile nitride may be deposited over the gates of nFETs.

Uniaxial stress is optimized to exert strain primarily in the direction along the channel. Since the stress layers may also operate as etch stops, this technique may be used on both nFETs and pFETs to create a dual etch-stop layer (dESL).

One stressor approach is to etch out the S/D area and replace it with a lattice mismatched material, such as epitaxial silicon germanium in pFETs. Due to the epitaxial deposition technique, the germanium atoms tend to substitutionally replace silicon atoms in the lattice without forming the compound SiGe. Germanium atoms are slightly larger than the lattice constant of silicon atoms, so epitaxial silicon germanium on a silicon channel yields compressive strain in the channel.

The increase in mobility from epitaxial silicon germanium in the S/D regions is a function of germanium concentration and proximity to the channel. The gain in drive current is influenced by the proximity of the S/D areas to the channel, and the germanium concentration in the film. The slope of the recess etch is also important. Sidewall spacer dimensions influence the S/D proximity to the channel.

The switching time for a CMOS transistor is proportional to its gate capacitance times voltage divided by current, where current is directly proportional to electron mobility in the source to drain channel. Thus, an increase in mobility may be used to decrease switching time and thereby increase operating frequency.

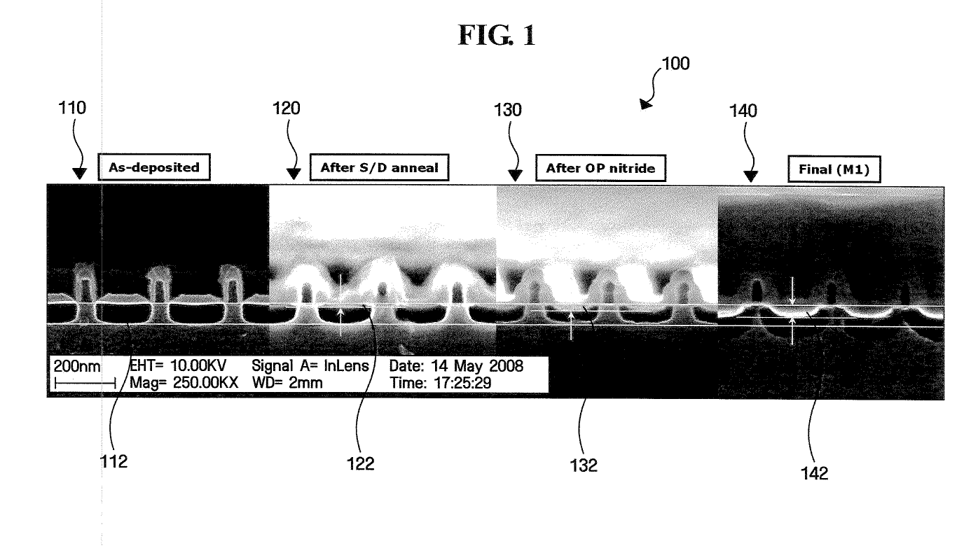

As shown in FIG. 1, a first embodiment pFET semiconductor device, analyzed with a virtual scanning electron microscope (VSEM) during step-by-step formation of an e-SiGe recess, is indicated generally by the reference numeral 100. Here, embedded silicon germanium (e-SiGe) is used to induce compressive stress in a pFET channel. As-deposited e-SiGe is recessed by the following annealing and etching processes, including S/D anneal, and OP nitride steps.

As deposited, the pFET device 110 includes a silicon source/drain (S/D) channel 112. After S/D anneal, the pFET device 120 has a top channel recess 122. Dry etching may be used to create a S/D recess anisotropically, or for an isotropically etched shape. After OP nitride, the pFET device 130 has a thicker top channel recess 132. Cleaning prior to epitaxial deposition may include an HF final step using SC1 and HF special pretreatment. At the final M1 stage, the pFET device 140 has an embedded silicon germanium (e-SiGe) recess 142. The e-SiGe SEG may include Ge at about 20% to about 30%, with in-situ boron doping.

The pFET device 140 has a somewhat improved operational speed as a result of the application of stress by e-SiGe to induce a compressive strain in the silicon S/D channel. Here, the e-SiGe induces a uniaxial compressive strain in the transistor channel region by the mechanism of a lattice mismatch. Unfortunately, the center region of e-SiGe is more recessed than the edge region of e-SiGe, which may lead to an undesirable reduction of the compressive stress.

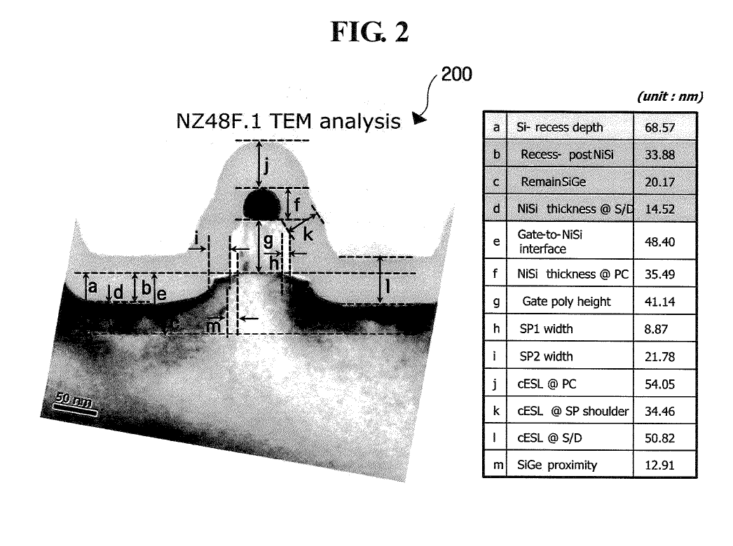

Turning to FIG. 2, a single pFET of the device 140 of FIG. 1 is indicated generally by the reference numeral 200. The pFET 200 has an e-SiGe shape measured via cross-sectional transmission electron microscopy (XTEM), here using an NZ48F.1 TEM analysis.

As shown, the si-recess depth “a” is 68.57 nm. The recess post NiSi “b” is 33.88 nm. The remaining SiGe “c” is 20.17 nm. The NiSi thickness @ S/D “d” is 14.52 nm. The gate-to-NiSi interface “e” is 48.40 nm. The NiSi thickness @ PC “f” is 35.49 nm. The gate poly height “g” is 41.14 nm. The first spacer SP1 width “h” is 8.87 nm. The second spacer SP2 width “i” is 21.78 nm. The cESL @ PC “i” is 54.05 nm. The cESL @ SP shoulder “k” is 34.46 nm. The cESL @ S/D “l” is 50.82 nm. The SiGe proximity “m” is 12.91 nm. Unfortunately, the recessed e-SiGe yields a reduced stress effect, which yields reduced increase in transistor performance.

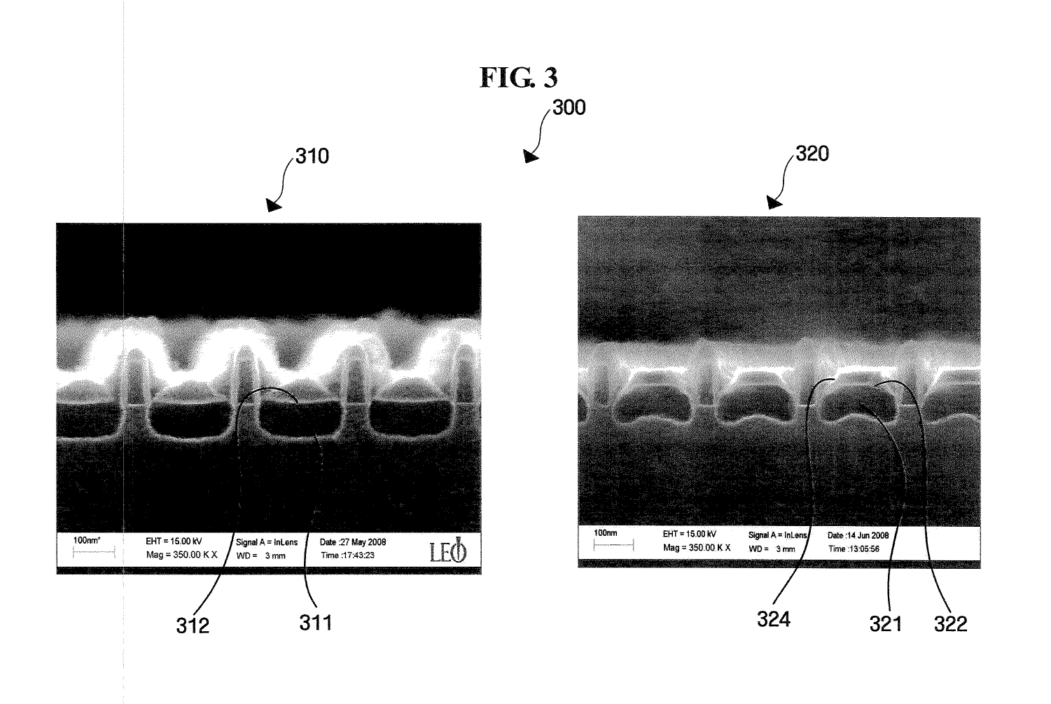

Turning now to FIG. 3, a comparison of the first embodiment e-SiGe shape with a second embodiment e-SiGe shape is indicated generally by the reference numeral 300. Here, a first embodiment pFET device 310 has an e-SiGe profile 311 with a top recess 312, which is a depressed recess towards the top center of the e-SiGe. A second embodiment pFET device 320 has an e-SiGe profile 321 with smaller top recesses 322 and 324, which are depressed towards the top ends of the e-SiGe. That is, the first embodiment has a relatively concave top surface of the e-SiGe, while the second embodiment has a relatively flat top surface of the e-SiGe at this stage. Moreover, the first embodiment e-SiGe profile has a relatively flat bottom surface, while the second embodiment has a relatively concave bottom surface. In addition, the first embodiment has a channel region that is substantially wider at the bottom than at the top, while the second embodiment has a channel region that has substantially the same width at the bottom as at the top.

Given an equal thickness e-SiGe layer as deposited, the concave or raised bottom center surface of the second embodiment profile 321 props up the top center surface of the e-SiGe profile to avert formation of a top center recess during the various annealing and/or etching processes. The substantial lack of any top center depression or concavity in the final e-SiGe profile of the second embodiment allows that e-SiGe profile to maintain a greater compressive stress on the transistor channel, resulting in further improved carrier mobility. In addition, the carrier mobility may have improved uniformity between pFETs in the second embodiment device 320. Moreover, the stress effect is increased as the volume of e-SiGe is increased, particularly adjacent to the channel region. Thus, an improved embedded stressor region profile may be obtained by addressing the recess shape of e-SiGe within the annealing, etching and salicidation processes.

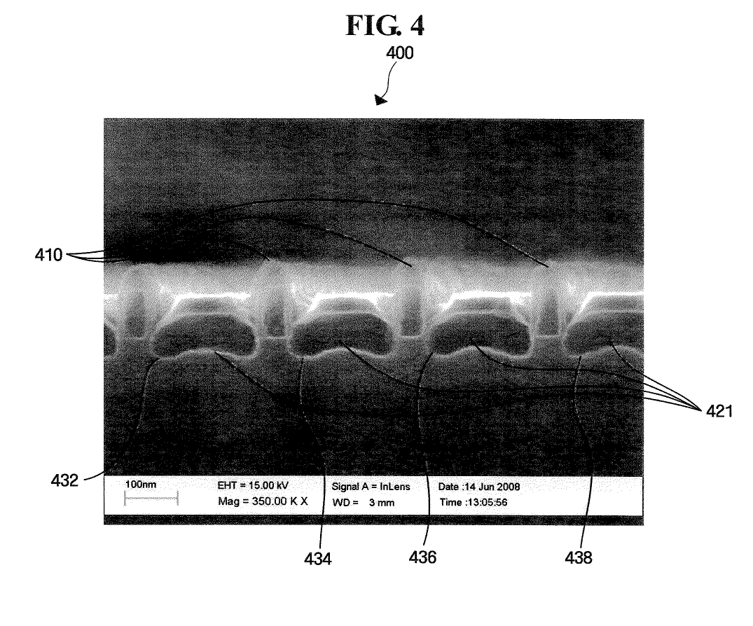

As shown in FIG. 4, a PMOS device in accordance with the second embodiment e-SiGe profile 321 of FIG. 3 is indicated generally by the reference numeral 400. The PMOS device 400 includes a plurality of pFETs 410, each having comparable e-SiGe profiles 421. As indicated, each profile has a substantially vertical end wall 432, a next lower wall section 434 offset relative to the previous wall section 432 at an included angle of about 121 degrees, a next wall section 436 offset relative to the previous wall section 434 at an included angle of about 151 degrees, a substantially horizontal next wall section 438 offset relative to the previous wall section 436 at an included angle of about 149 degrees, and a next wall section offset relative to the previous wall section at an included angle of about 205 degrees, respectively.

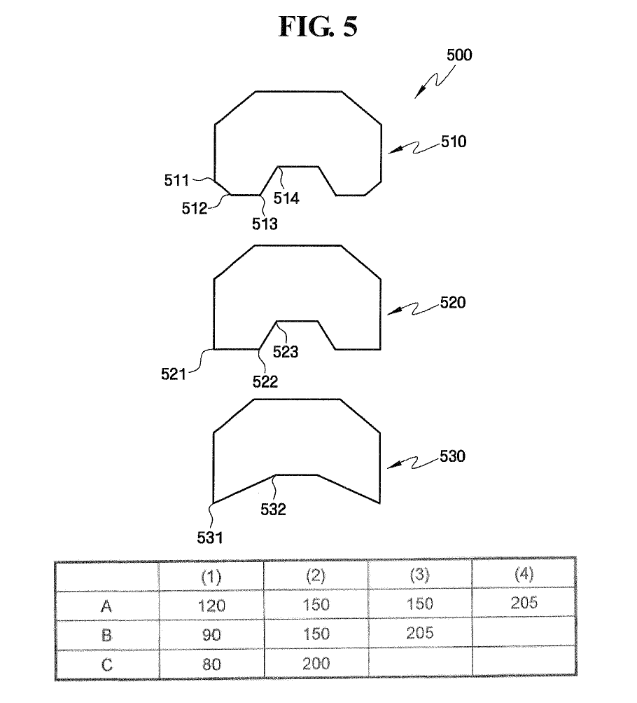

Turning to FIG. 5, three additional embodiment embedded stressor region profiles are indicated generally by the reference numeral 500. Here, a third embodiment embedded stressor region profile 510 has left lower walls, beginning from the left side and moving counter-clockwise relative to the previous walls, with included angles 511 of 120 degrees, 512 of 150 degrees, 513 of 150 degrees, and 514 of 205 degrees, respectively.

A fourth embodiment embedded stressor region profile 520 has left lower walls, beginning from the from the left side and moving counter-clockwise relative to the previous wall section, with included angles 521 of 90 degrees, 522 of 150 degrees, and 523 of 205 degrees, respectively. A fifth embodiment embedded stressor region profile 530 has left lower walls, beginning from the from the left side and counter-clockwise relative to the previous wall section, with included angles 531 of 80 degrees, and 532 of 200 degrees, respectively.

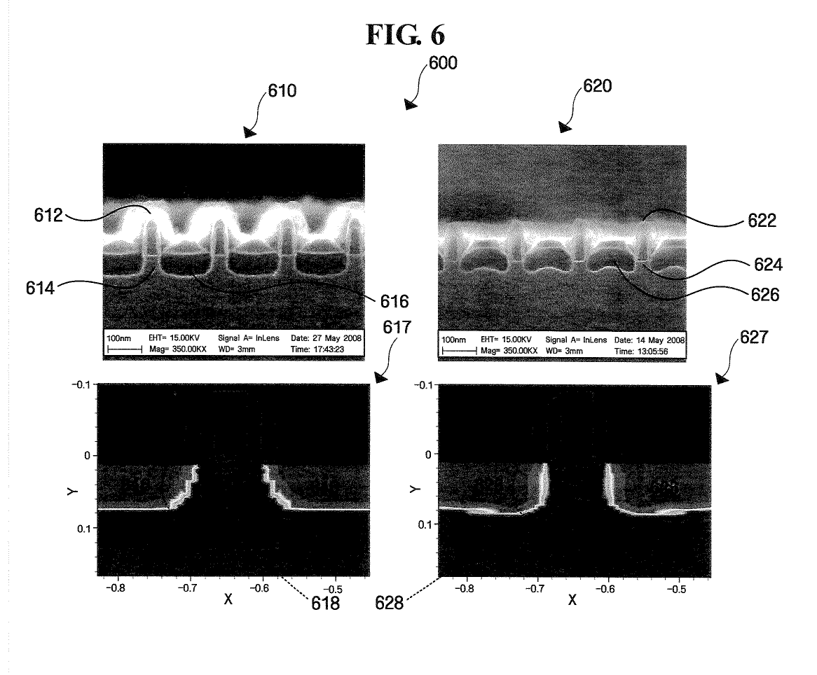

Turning now to FIG. 6, a comparison of stressor region profiles and resulting stress contours is indicated generally by the reference numeral 600. Here, a device 610, similar to that of the first embodiment of FIGS. 1 and 2, includes a transistor 612 having a S/D channel 614. A strain is induced in the channel 614 by stressor region profiles 616 to either side of the channel. The uniaxial stress contour from the stressor region profiles is shown in the stress diagram 617. As indicated, the stress contours 614 at the end walls 618 of the stressor regions 616 are substantially tilted.

In comparison, a device 620, similar to that of the second through fifth embodiments of FIGS. 4 and 5, includes a transistor 622 having a S/D channel 624. A strain is induced in the channel 624 by stressor region profiles 626 to either side of the channel. The uniaxial stress contour from the stressor region profiles is shown in the stress diagram 627. As indicated, the stress contours 624 at the end walls 628 of the stressor regions 626 are substantially vertical. Substantially vertical stress contours are more effective at inducing greater and more uniform strain in the channels versus substantially tilted stress contours.

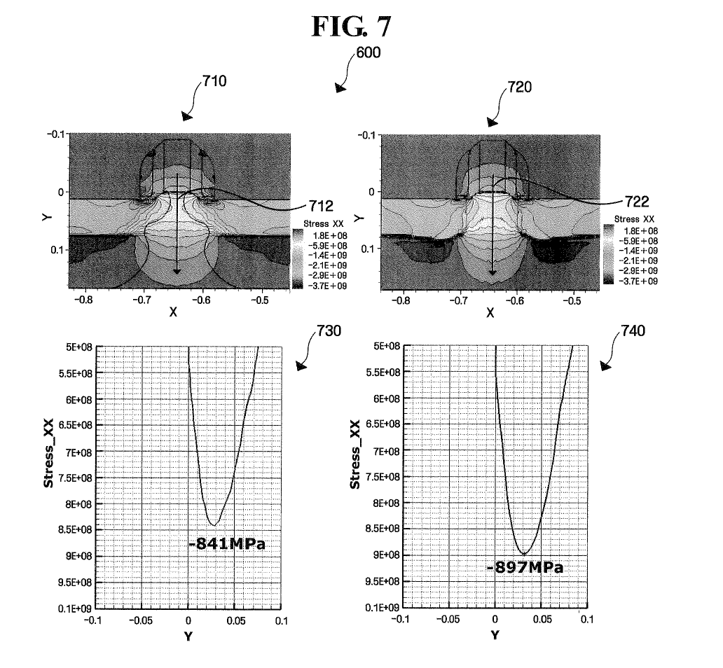

As shown in FIG. 7, strain contours for the stressor profiles of FIG. 6 are indicated generally by the reference numeral 700. Here, a strain contour 710 is shown for the device 610 of FIG. 6. A plot 730 indicates the uniaxial stress in the x or channel direction for values taken along the y or vertical direction line 712. Here, the compressive stress at the center of the channel has a maximum of about −841 MPa, and the stress towards the top and bottom of the channel is only on the order of about −830 MPa.

In comparison, a strain contour 720 is shown for the device 620 of FIG. 6, A plot 740 indicates the uniaxial stress in the x or channel direction for values taken along the y or vertical direction line 722. Here, the compressive stress at the center of the channel has a maximum of about −897 MPa, and the stress towards the top and bottom of the channel is on the order of about −890 MPa.

Thus, the embodiment 620 of FIG. 6 applies a greater and more uniform stress in the channel than does the embodiment 610 of FIG. 6. That is, stress in the channel is shown to increase from −841 MPa to −897 MPa.

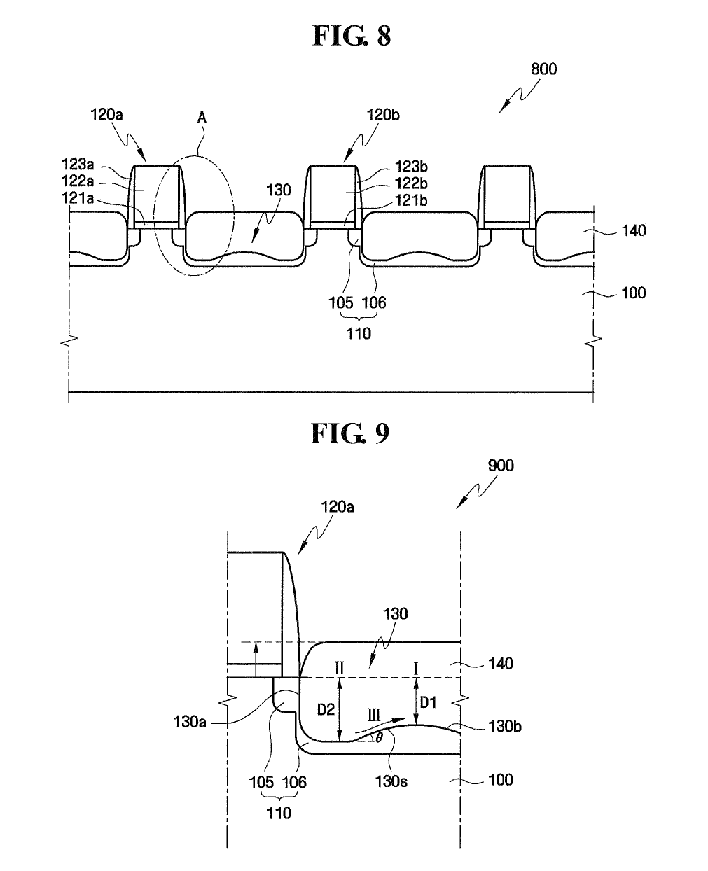

Turning to FIG. 8, a semiconductor device according to a sixth embodiment is indicated generally by the reference numeral 800. The device 800 includes a substrate 100. First and second transistors 120a and 120b, respectively, are disposed on the substrate 100.

The transistor 120a includes a gate insulation film 121a, a gate electrode 122a disposed on the gate insulation film, and a spacer 123a disposed on the sides of the transistor. Likewise, the transistor 120b includes a gate insulation film 121b, a gate electrode 122b disposed on the gate insulation film, and a spacer 123b disposed on the sides of the transistor. A Trench 130 is disposed between the first transistor 120a and the second transistor 120b.

There is a source/drain (S/D) region 110 disposed at each end of the trench 130. Each S/D region 110 includes an extension S/D 105 and a deep S/D 106.

Turning now to FIG. 9, a region A of FIG. 8 is shown in enlarged detail and indicated generally by the reference numeral 800. The trench 130 is shown where it abuts the transistor 120a. The trench 130 includes a trench sidewall 130a, a trench bottom 130b, a trench incline 130s, and an epitaxial layer 140 such as SiGe. Here, the vertical dimension D1 is taken at “I” between the layer 140 and the bottom 130b, and the vertical dimension D2 is taken at “II” between the layer 140 and the bottom 130b. The average slope angle at “III” between the trench bottom at D2 and the trench bottom at D1 is an acute angle Theta. D1 is less than D2.

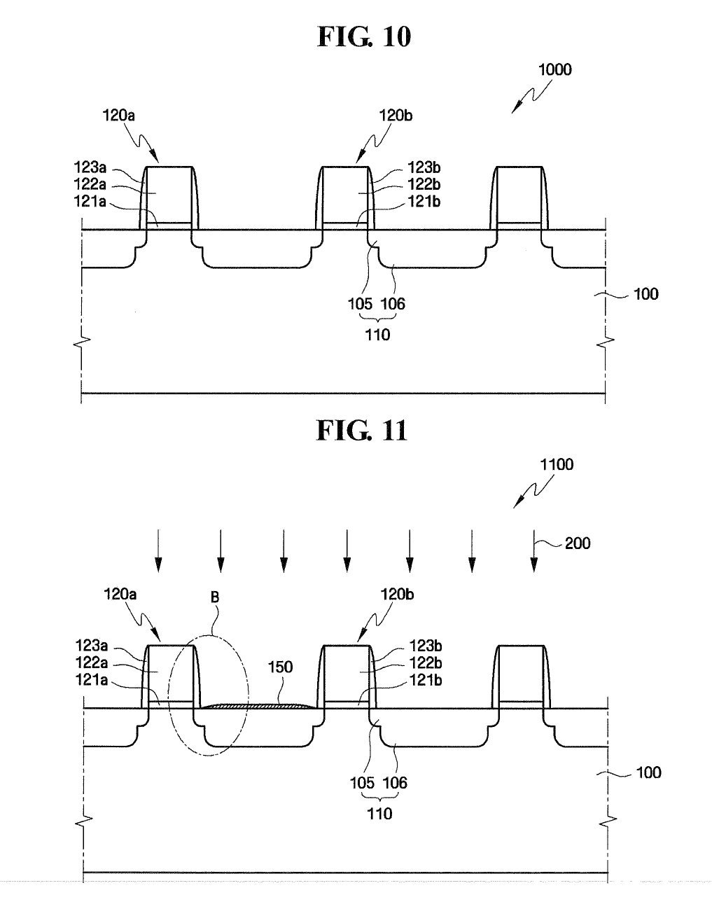

FIGS. 10 through 14 illustrate the method of fabricating the sixth embodiment device of FIGS. 8 and 9. As shown in FIG. 10, a device 1000 includes a substrate 100, with first and second transistors 120a and 120b, disposed on the substrate 100, respectively.

The transistor 120a includes a gate insulation film 121a, a gate electrode 122a disposed on the gate insulation film, and a spacer 123a disposed on the sides of the transistor. Likewise, the transistor 120b includes a gate insulation film 121b, a gate electrode 122b disposed on the gate insulation film, and a spacer 123b disposed on the sides of the transistor. A S/D region 110 is disposed under each spacer 123a and 123b. Each S/D region 110 includes an extension S/D 105 and a deep S/D 106.

Turning to FIG. 11, the device of FIG. 10 during a subsequent processing step is indicated generally by the reference numeral 1100. The device 1100 includes the features described for the device 1000 of FIG. 10, so duplicate description may be omitted. In addition, a plasma process 200 is now used to deposit an oxidation layer 150 on the surface of the substrate 100.

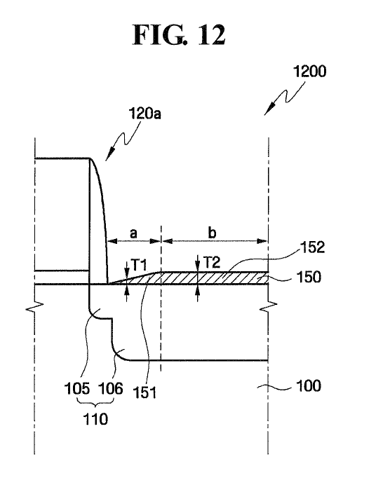

Turning now to FIG. 12, a region B of FIG. 11 is shown in enlarged detail and indicated generally by the reference numeral 1200. The oxidation layer 150 includes a first portion 151 disposed in a region “a” beginning from the edge of the transistor 120a, the first portion 151 having a positive slope and an average thickness T1, and a second portion 152 disposed in a region “b” that is farther from the transistor 120a and extending towards the next transistor 120b, the second portion 152 having a thickness T2. Here, the thickness of first oxidation layer portion T1 is less than the thickness of the second oxidation layer portion T2 due to the blocking effect of the transistor 120a′s gate structure.

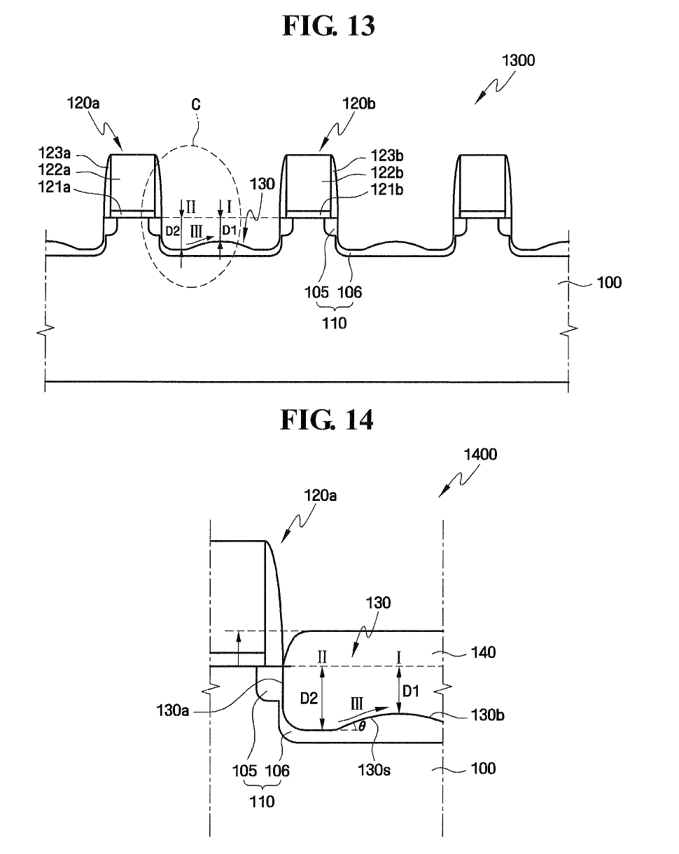

As shown in FIG. 13, the device of FIG. 11 during a subsequent processing step is indicated generally by the reference numeral 1300. The device 1300 includes the features described for the device 1100 of FIGS. 11 and 1000 of FIG. 10, so duplicate description may be omitted. In addition, a trench 130 is now formed between the first transistor 120a and the second transistor 120b.

Turning to FIG. 14, a region C of FIG. 13 is shown in enlarged detail and indicated generally by the reference numeral 1400. The trench 130 includes a trench sidewall 130a, a trench bottom 130b, a trench incline 130s, and an epitaxial layer 140 such as SiGe. Here, the vertical dimension D1 is taken at “I” between the layer 140 and the bottom 130b, and the vertical dimension D2 is taken at “II” between the layer 140 and the bottom 130b. The average slope angle at “III” between the trench bottom at D2 and the trench bottom at D1 is an acute angle Theta. D1 is less than D2.

The trench 130 is formed in the source/drain region by an anisotropic etching process. Since the oxidation layer 150 having the first and second portions 151 and 152 with varying thicknesses T1 and T2, respectively, is used as an etching mask, the bottom surface of the resulting trench 130 is inclined.

In a pFET embodiment, the epitaxial growth of SiGe is conducted in the S/D trench. Thus, the e-SiGe region is defined by sidewall surfaces 130a, and by bottom surfaces 130b and 130s. It shall be understood that the bottom surfaces 130s are formed with an acute angle to the principal surface direction of the silicon substrate.

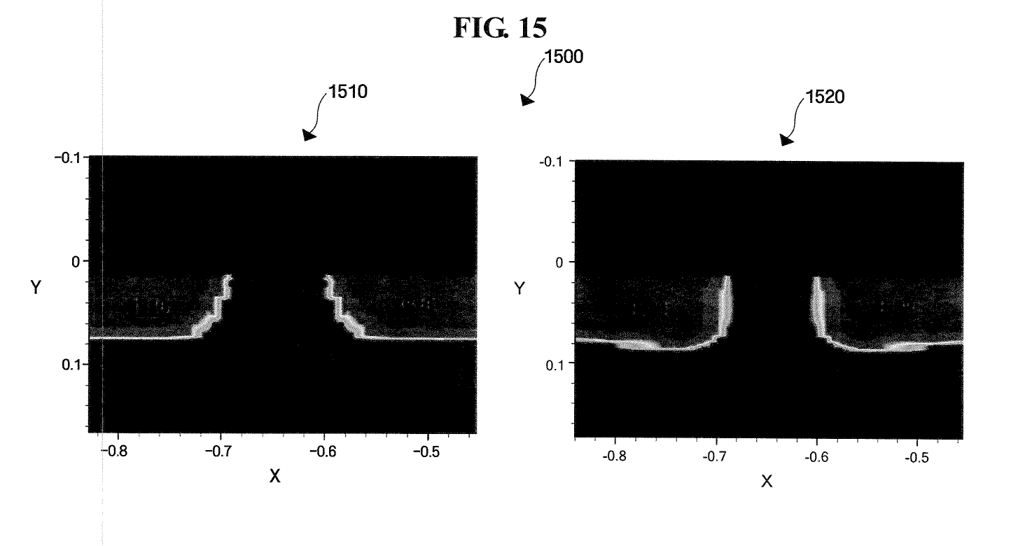

Turning now to FIG. 15, a comparison of stressor region profiles is indicated generally by the reference numeral 1500. The comparison shows a first stressor region profile 1510 for the first embodiment of FIGS. 1 and 2, exhibiting uniaxial stress contours 1516. As indicated, the stress contours 1516 are substantially tilted relative to the channel. In comparison, a second stressor region profile 1520 for the sixth embodiment of FIGS. 8 through 14 exhibits uniaxial stress contours 1526, where the stress contours 1526 are substantially vertical relative to the channel. Substantially vertical stress contours are more effective at inducing greater and more uniform strain in the channels versus substantially tilted stress contours.

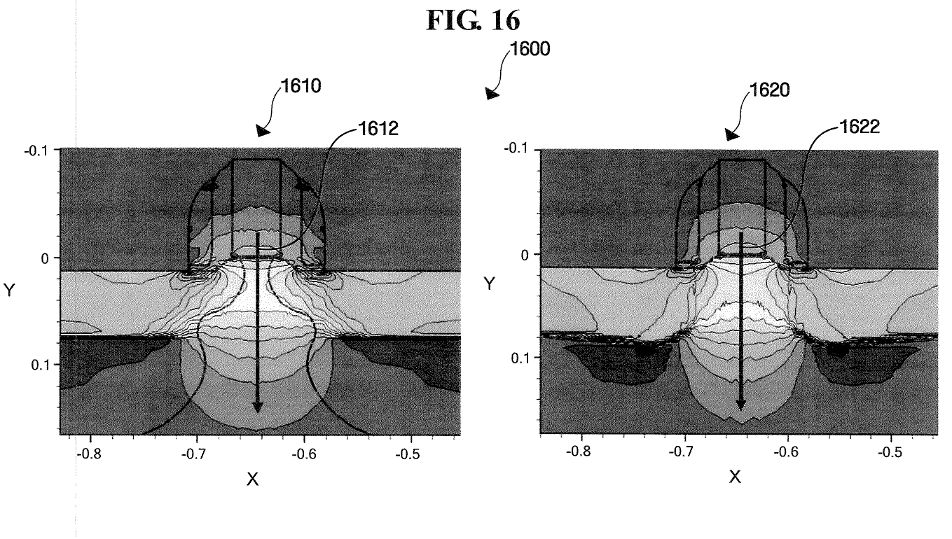

As shown in FIG. 16, induced strain contours for the stressor profiles of FIG. 15 are indicated generally by the reference numeral 1600. Here, a strain contour 1610 is shown for the device 200 of FIG. 2. In comparison, another strain contour 1520 is shown for the device 1400 of FIG. 14.

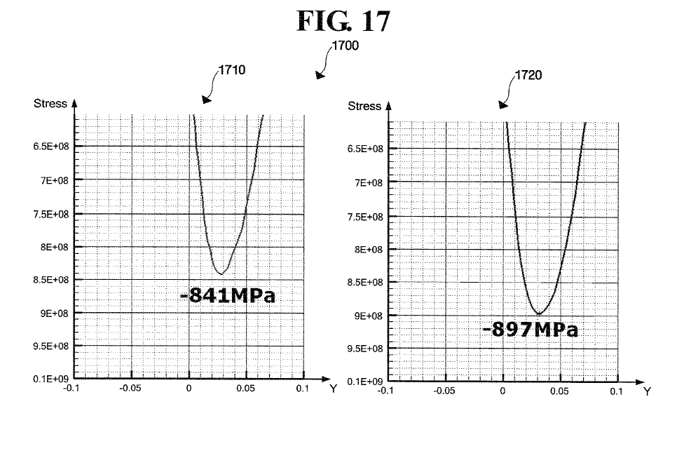

Turning to FIG. 17, stress versus strain plots for the stress contours of FIG. 15 and the strain contours of FIG. 16 are indicated generally by the reference numeral 1700. Here, the plot 1710 indicates the uniaxial stress in the x or channel direction for values taken along the y or vertical direction line 1612 of FIG. 16. As shown, the compressive stress at the center of the channel has a maximum of about −841 MPa, and the stress towards the top and bottom of the channel is only on the order of about −830 MPa.

In comparison, a plot 1720 indicates the uniaxial stress versus strain in the x or channel direction for values taken along the y or vertical direction line 1622 of FIG. 16. Here, the compressive stress at the center of the channel has a maximum of about −897 MPa, and the stress towards the top and bottom of the channel is on the order of about −890 MPa.

Thus, the profile embodiment 1400 of FIG. 14 applies a greater and more uniform stress in the channel than does the profile embodiment 200 of FIG. 2. That is, stress in the channel is shown to increase from −841 MPa to −897 MPa.

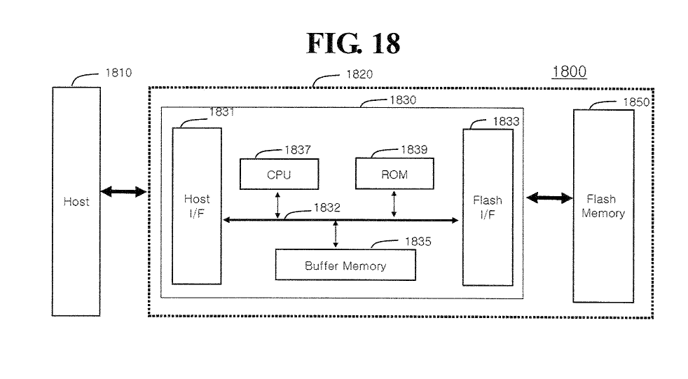

As shown in FIG. 18, a flash memory card system is indicated generally by the reference numeral 1800. The system 1800 may be a portable electronic device, such as a computer, digital camera, digital music player, cellular telephone, personal data assistant (PDA), or the like. The system 1800 includes a host 1810 in signal communication with a flash card 1820. The flash card 1820 may be a solid-state disk (“SSD”), SD card, MMC, Memory Stick, an embedded card such as movi-NAND®, Flex-OneNAND®, One-NAND®, GBNAND, iNAND, or the like.

The flash card 1820 includes a controller 1830 in signal communication with a flash memory 1850. Here, the flash memory 1850 is a strained semiconductor NAND flash memory having e-SiGe stressors of improved shape abutting the pFET channels and embedded silicon carbon (e-SiC) stressors abutting the nFET channels.

The host 1810 communicates with the flash memory 1850 using a flash translation layer (“FTL”), which may include logic and/or firmware used to effectively manage the card 1820. The FTL may be stored or implemented in the controller 1830 or in the flash memory 1850.

The controller 1830 includes a host interface 1831 in signal communication with a controller bus 1832, a flash interface 1833 in signal communication with the controller bus 1832, a buffer memory 1835 in signal communication with the controller bus 1832, a CPU 1837 in signal communication with the controller bus 1832, and a ROM 1839 in signal communication with the controller bus 1832.

These and other features of the present disclosure may be readily ascertained by one of ordinary skill in the pertinent art based on the teachings herein. Although illustrative embodiments have been described herein with reference to the accompanying drawings, it is to be understood that the present disclosure is not limited to those precise embodiments, and that various other changes and modifications may be effected therein by those of ordinary skill in the pertinent art without departing from the scope or spirit of the present disclosure. For example, the exemplary methods and profiles for pFETs with embedded silicon germanium (e-SiGe) may be used in conjunction with comparable methods and profiles for nFETs with embedded silicon carbon (e-SiC) in a CMOS device, to balance the relative performances of the pFETs and nFETs, respectively. All such changes and modifications are intended to be included within the scope of the present disclosure as set forth in the appended claims.

What is claimed is:

1. A strained semiconductor device comprising:
a plurality of transistors, each having a gate disposed over a channel region; and
elongated stress regions disposed between adjacent channel regions,
wherein each of the elongated stress regions has a lower boundary that is deeper towards its ends than towards its center.

2. The device of claim 1 wherein each of the elongated stress regions has a substantially non-concave upper boundary.

3. The device of claim 1 wherein each of the elongated stress regions has an upper boundary at least as high as the gate.

4. The device of claim 1 wherein the channel regions are positively charged.

5. The device of claim 1 wherein each of the plurality of transistors is a positive-channel field effect transistor (pFET).

6. The device of claim 1 wherein the stress regions are expansive.

7. The device of claim 1 wherein the stress regions exert compressive stress against the channel regions.

8. The device of claim 1 wherein the stress regions comprise embedded silicon-germanium (e-SiGe).

9. The device of claim 1 wherein the lower boundary of each elongated stress region is substantially concave.

10. The device of claim 1, further comprising a substrate region disposed beneath each stress region, wherein the substrate region has an upper boundary that is substantially convex.

11. The device of claim 1, further comprising a source/drain (S/D) region disposed beneath each stress region, wherein the S/D region has an upper boundary that is substantially convex.

12. The device of claim 1, further comprising an etch stop layer (ESL) disposed above each stress region, wherein the ESL has a lower boundary that is substantially flat.

13. The device of claim 1 wherein the stress region has an upper boundary that is at least as high as a top of the channel.

14. The device of claim 1 wherein the channel has substantially vertical sidewalls.

15. The device of claim 1 wherein the lower boundary of the stress region meets its ends with an included angle between about 80 degrees to about 120 degrees.

16. The device of claim 1 wherein the elongated stress region has an upper boundary that is at least as high towards its center as it is at its ends.

17. The device of claim 1 wherein one end of the elongated stress region is disposed at a source or drain of a first transistor, and the other end of the elongated stress region is disposed at a drain or source of the second transistor.

18. The device of claim 1 wherein the stress regions have substantially vertical boundaries at the channel regions.

19. A method of forming a strained semiconductor device, the method comprising:
forming a plurality of transistors on a substrate, each transistor having a gate disposed over a channel region;
at least one of etching or annealing an elongated trench between adjacent channel regions, where the trench has a lower boundary that is deeper towards its ends than towards its center; and
conformably embedding an elongated stress region in the trench between adjacent channel regions.

20. The method of claim 19 wherein the embedded stress region has a substantially non-concave upper boundary.

21. The method of claim 19 wherein the embedded stress region has an upper boundary at least as high as the gate.

22. The method of claim 19 wherein the stress regions have substantially vertical boundaries at the channel regions.

23. The method of claim 19 wherein the channel region is positively charged and the stress region comprises embedded SiGe.

24. The method of claim 19, further comprising forming an elongated oxidation layer between first and second transistors prior to forming the trench, the oxidation layer having one thickness towards its center, and a sloping reduced thickness towards it ends.

25. The method of claim 24 wherein the oxidation layer is formed by plasma deposition.

26. The method of claim 19 wherein the center of the trench is elevated at an acute angle relative to the ends of the trench.

27. The method of claim 19 wherein the etching is anisotropic.

28. A memory card device having a strained semiconductor NAND flash memory, the NAND flash memory comprising:
a plurality of transistors, each having a gate disposed over a channel region; and
elongated stress regions disposed between adjacent channel regions,
wherein each of the elongated stress regions has a lower boundary that is deeper towards its ends than towards its center.

29. The memory card device of claim 28 wherein each of the elongated stress regions has a substantially non-concave upper boundary.

30. The memory card device of claim 28 wherein each of the elongated stress regions has an upper boundary at least as high as the gate.

31. The memory card device of claim 28 wherein the channel regions are positively charged.

32. The memory card device of claim 28 wherein each of the plurality of transistors is a positive-channel field effect transistor (pFET).

33. The memory card device of claim 28 wherein the stress regions are expansive.

34. The memory card device of claim 28 wherein the stress regions exert compressive stress against the channel regions.

35. The memory card device of claim 28 wherein the stress regions comprise embedded silicon-germanium (e-SiGe).

36. The memory card device of claim 28 wherein the lower boundary of each elongated stress region is substantially concave.

37. The memory card device of claim 28, further comprising a substrate region disposed beneath each stress region, wherein the substrate region has an upper boundary that is substantially convex.

38. The memory card device of claim 28, further comprising a source/drain (S/D) region disposed beneath each stress region, wherein the S/D region has an upper boundary that is substantially convex.

39. The memory card device of claim 28, further comprising an etch stop layer (ESL) disposed above each stress region, wherein the ESL has a lower boundary that is substantially flat.

40. The memory card device of claim 28 wherein the stress region has an upper boundary that is at least as high as a top of the channel.

41. The memory card device of claim 28 wherein the channel has substantially vertical sidewalls.

42. The memory card device of claim 28 wherein the lower boundary of the stress region meets its ends with an included angle between about 80 degrees to about 120 degrees.

43. The memory card device of claim 28 wherein the elongated stress region has an upper boundary that is at least as high towards its center as it is at its ends.

44. The memory card device of claim 28 wherein one end of the elongated stress region is disposed at a source or drain of a first transistor, and the other end of the elongated stress region is disposed at a drain or source of the second transistor.

45. The memory card device of claim 28 wherein the stress regions have substantially vertical boundaries at the channel regions.
